(19) United States
(12) Patent Application Publication
(10) Pub. No.: US 2026/0205095 A1
(43) Pub. Date: Jul. 16, 2026

(54) LOW-PASS ACTIVE FILTER FOR A MOTOR-DRIVING PWM SIGNAL

(71) Applicant: Etel S.A., Môtiers (CH)

(72) Inventors: Gabriele Gualco, Sassel (CH); Carole Erb, Couvet (CH); Pierre Hirsig, Neuchatel (CH); Cyrille Savy, Saint-Aubin-Sauges (CH); Eric Tissot, Les Fourgs (FR); Daniel Pfister, Fleurier (CH); Gaëtan Matthey-Doret, Fleurier (CH); Raffaele Tedesco, La Chaux-de-Fonds (CH)

(21) Appl. No.: 19/412,919

(22) Filed: Dec. 9, 2025

(30) Foreign Application Priority Data
Jan. 13, 2025 (EP) 25151538.3

(51) Int. Cl. H03H 11/12; G01R 15/18; G01R 19/00; G03F 7/00; H02P 27/08; H03G 3/30; H10P 72/50

(52) U.S. Cl. CPC H03H 11/12; G01R 15/18; G01R 19/0092; G03F 7/70716; G03F 7/70758; G03F 7/70991; H02P 27/08; H03G 3/30; H10P 72/50

(57) ABSTRACT

A low-pass active filter for a motor-driving PWM signal generated by a power inverter, including a first transformer having a primary and secondary winding, a first low-pass passive filtering circuit arranged to filter an output signal of the primary winding, a current sensor for measuring a current flowing on the low-pass active filter, and an amplifier configured to generate and inject a compensating current into the secondary winding. The compensating current is the current measured by the current sensor multiplied by a gain of the amplifier. The primary winding of the first transformer is an inductor component of the first low-pass passive filtering circuit. A gain of the amplifier is determined such that the compensating current is adapted to counteract a high-frequency PWM voltage component in the motor-driving PWM signal through a mutual inductance of the first transformer to at least attenuate ripple in the motor-driving PWM signal.

### CROSS REFERENCE TO RELATED APPLICATIONS

This application claims benefit to European Patent Application No. EP 25151538.3, filed on Jan. 13, 2025, which is hereby incorporated by reference herein.

### FIELD

The present invention relates to a low-pass active filter for a PWM signal for driving an electric motor such as a synchronous or a DC motor, a linear electric motor comprising the low-pass active filter as well as an X-Y positioning stage for semiconductor equipment.

### BACKGROUND

Inverters or Class-D amplifiers conventionally used to drive electric motors have now reached precision levels comparable to those of linear amplifiers. However, despite this improved precision, they still produce unwanted electrical disturbances at the PWM frequency since such PWM frequency introduces ripple in the motor's current and voltage waveform which causes force fluctuations when the electric motor is operating. These force fluctuations may cause oscillations in the motor's mover leading to mechanical vibrations of the load, thereby causing positioning errors which may have a significant negative impact for high precision positioning machines used in the semiconductor industry.

To address unwanted ripple, various solutions have been proposed in the literature, including the use of hybrid linear/Class-D amplifiers and passive filters, such as disclosed in EP0682401B1.

Hybrid linear/Class-D amplifiers such as disclosed in EP2388910B1 and U.S. Pat. No. 6,396,933B1 can completely suppress these unwanted disturbances, but their use is limited to low-voltage applications, around 100 V, where linear amplifiers can be effectively designed. Hybrid linear/Class-D amplifiers are therefore not adapted in the context of motor drives for electric motors used in semiconductor positioning systems where a voltage well above 200 Volts, for example 300 or even 600 Volts, is usually required.

In a typical Class-D amplifier employed as a motor inverter, the high-voltage square wave output directly powers the motor. However, as noted earlier, the high-voltage PWM signals can introduce unacceptable levels of electromagnetic disturbance to sensitive high-precision measurement equipment. These disturbances can be mitigated to acceptable levels through the implementation of passive filters such as the RLC low pass filter to achieve the desired attenuation at the specified disturbance frequency.

The use of larger inductance values can help achieve a smoother voltage output since it better resists rapid changes in current, filtering out more high-frequency components of the motor driving PWM signal. Yet, larger inductance values often require physically larger components which can exceed the available space. In addition, the inductor must avoid saturation across the entire operating current range, which complicates achieving high inductance values. A multi-stage filter design is often a better alternative, although it may still result in substantial device size which is not adapted in case of volume limitations.

### SUMMARY

In an embodiment, the present disclosure provides a low-pass active filter for a motor-driving PWM signal generated by a power inverter in an electric motor drive, comprising a first transformer having a primary winding and a secondary winding, a first low-pass passive filtering circuit arranged to filter an output signal of the primary winding to power the electric motor, a current sensor for measuring a current flowing on the low-pass active filter, and an amplifier configured to generate and inject a compensating current into the secondary winding. The compensating current is the current measured by the current sensor multiplied by a gain of the amplifier. The primary winding of the first transformer is an inductor component of the first low-pass passive filtering circuit. A gain of the amplifier is determined such that the compensating current is adapted to counteract a high-frequency PWM voltage component in the motor-driving PWM signal through a mutual inductance of said first transformer in order to at least attenuate ripple in the motor-driving PWM signal.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 illustrates an electrical diagram of a low-pass active filter for filtering out the PWM component of a PWM signal, according to an embodiment;

FIG. 2 illustrates an electric diagram of the passive filtering circuit of the low-pass active filter of FIG. 1;

FIG. 3 illustrates an electric diagram of a passive filtering circuit of the low-pass active filter according to an embodiment;

FIG. 4 and FIG. 5 are partial electric diagrams of the low pass active filter with other arrangements of the current sensor, according to embodiments;

FIG. 6 illustrates a block diagram of a low-pass active filter, similar to the low-pass active filter of FIG. 1, further comprising a high-pass filter to extract high-frequency components of the output signal of the power inverter;

FIG. 7 illustrates an electric diagram of the low-pass active filter comprising an OTA with a feedback loop according to an embodiment;

FIG. 8 illustrates an electric diagram the low-pass active filter comprising a second transformer for current measurement and an OTA connected to the terminal of the secondary winding of this second transformer according to an embodiment;

FIG. 9 illustrates an electric diagram of the low-pass active filter comprising an additional filtering circuit connected to the output of the inverter, according to an embodiment;

and

FIG. 10 illustrates a simulation of the low-pass active filter showing a 300V PWM voltage at an input.

### DETAILED DESCRIPTION

In an embodiment, the present disclosure provides a low-pass active filter for a motor-driving PWM signal that addresses the above-limitations.

More particularly, an embodiment of the present disclosure provides a low-pass active filter for a motor-driving PWM signal comprising an improved ratio of filter size to filtering performance.

An embodiment of the present disclosure provides a linear electric motor, such as a synchronous motor wherein the mover is made of coils powered by a DC voltage.

An embodiment of the present disclosure provides an X-Y positioning stage with a positioning accuracy at the nanometre or sub-nanometre level.

According to the present disclosure, the above-mentioned advantages are achieved by a low-pass active filter for a motor-driving PWM signal generated by a power inverter in an electric motor drive. The active filter comprises a first transformer having a primary winding and a secondary winding, a first low-pass passive filtering circuit arranged to filter the output signal of said primary winding in order to power the electric motor, a current sensor for measuring a current flowing on the active filter and an amplifier configured to generate and inject a compensating current into said secondary winding. The compensating current is the current measured by the current sensor multiplied by the gain of the amplifier. The primary winding of the first transformer is the inductor component of the first low-pass passive filtering circuit. The gain of the amplifier is determined such that said compensating current is adapted to counteract the high-frequency PWM voltage component in the motor-driving PWM signal through the mutual inductance of said first transformer in order to at least attenuate ripple in said signal.

In an embodiment, the low-pass active filter further comprises a high-pass filter to extract high-frequency components of the output signal of the power inverter from the compensating current before the injection of said compensating current into said secondary winding.

In an embodiment, the high-pass filter is arranged between the current sensor and the amplifier.

In an embodiment, the current sensor is arranged on the input side or on the output side of the primary winding of the first transformer.

In an embodiment, the current sensor is arranged to measure current flowing in the RC branch of said first low-pass passive filtering circuit.

In an embodiment, the current sensor is a second transformer having a primary winding and a secondary winding. The output of the primary winding is connected to an input of the primary winding of the first transformer. The amplifier inputs are connected to the terminals of the secondary winding of the second transformer. The output of the amplifier is injected into the secondary winding of the first transformer.

In an embodiment, the amplifier is an operational transconductance amplifier (OTA), a linear amplifier or a class-D amplifier.

In an embodiment, the low-pass active filter further comprises a second low-pass passive filtering circuit arranged to be connected to the output of the inverter and to filter out the PWM signal before measurement of the current by the sensor current.

In an embodiment, the first low-pass passive filtering circuit comprises at least a capacitance and a resistance in series arranged in parallel with said inductor component.

In an embodiment, the first low-pass passive filtering circuit further comprises another inductor arranged in series with said resistance and capacitance.

In an embodiment, the output of the secondary winding of the first transformer is connected to ground.

An aspect of the present disclosure relates to a motor drive comprising at least one power inverter and at least one low-pass active filter, according to any of the above embodiments, to filter out the output of the power inverter.

An aspect of the present disclosure relates to an electric motor, in particular a synchronous motor, comprising the above motor drive.

An aspect of the present disclosure relates to an X-Y positioning stage for a semiconductor processing equipment, in particular a photolithography machine or a wafer inspection system, comprising one or more of the above electric motor.

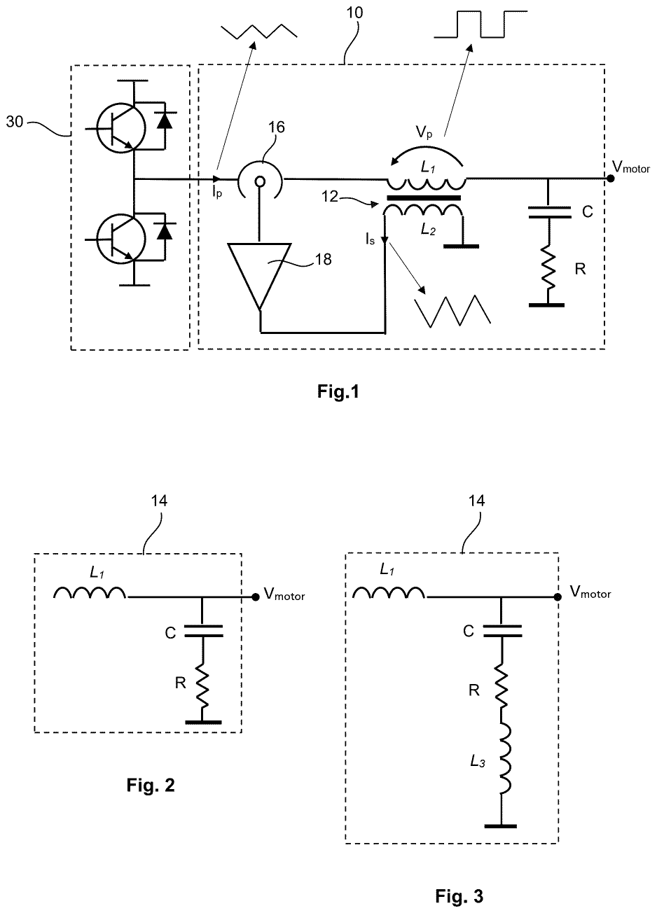

With reference to FIG. 1, the low-pass active filter 10 is arranged to filter out Pulse Width Modulated (PWM) signal generated by the power inverter 30. A Class-D amplifier can be used as power inverter to generate PWM signals. In this respect, a PWM generator comprises a carrier generator configured to generate a carrier. The carrier is fed into a comparator together with a reference signal to output a PWM signal which is fed to the gate drivers of the Class D amplifier.

The low-pass active filter 10 comprises a transformer 12 having a primary winding L₁ and a secondary winding L₂. The primary winding L₁ of the transformer 12 forms together with the capacitance C and the resistance R a low-pass passive filtering circuit 14, as shown in FIG. 2, arranged to filter out or at least mitigate the ripple of the output signal Vₘₒₜₒᵣ so as to improve motor performance by reducing vibration, heating and noise while increasing efficiency and control. The primary winding L₁ of the first transformer 12 acts as the inductor component of the low-pass passive filtering circuit 14.

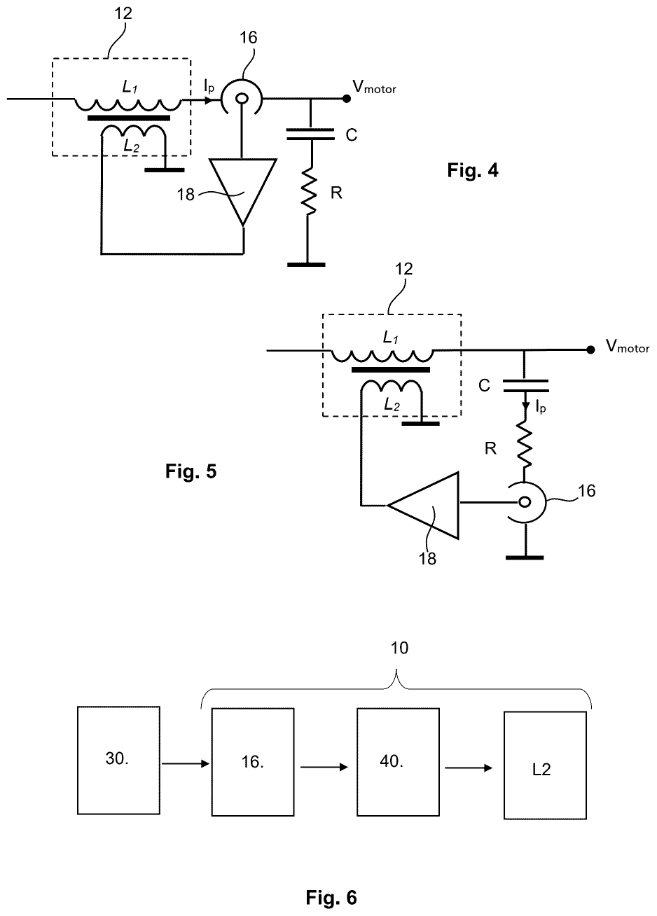

The low-pass active filter 10 further comprises a current sensor 16 for measuring a current Iₚ output by the inverter 30 (e.g. Class-D amplifier) of a triangular waveform. The current sensor 16 can be arranged at a different location to measure the current Iₚ. In the embodiment of FIG. 1, the current sensor 16 is arranged to measure the current Iₚ flowing on the input side of the primary winding L₁ of the transformer 12. In another embodiment shown in FIG. 4, the current sensor 16 of the low-pass active filter is arranged to measure the current Iₚ flowing on the output side of the primary winding L₁ of the transformer 12. In yet another embodiment shown in FIG. 5, the current sensor 16 is arranged to measure current flowing in the RC branch of the low-pass passive filtering circuit. The current can be measured for example with a shunt resistance or with a second transformer as described below.

With reference to FIG. 1, the low-pass active filter 10 also comprises an amplifier 18 configured to generate and inject a compensating current Iₛ into the secondary winding L₂ of the transformer 12. The compensating current Iₛ is a replica of the triangle waveform of the current Iₚ output by the inverter 30 with a typically greater amplitude. The required amplitude can be tuned when selecting the number of turns of the transformer windings. The amplifier can be a linear amplifier, a class-D amplifier or an operational transconductance amplifier (OTA), as described subsequently.

With reference to FIG. 6, the low-pass active filter 10 can further comprise a high-pass filter 40 to extract high-frequency components of the output signal of the power inverter 30 from the compensating current before the injection of the latter into the secondary winding L₂ of the transformer 12. The high-pass filter 40 is used to remove low-frequency components that can be present in the PWM signal, in particular the low-frequency sinusoidal voltages used to control the motor. These low frequency components of the PWM signal are not part of the portion of the signal which needs to be cancelled or at least mitigated at the output of the low-pass active filter 10.

According to an ideal scenario, a steady state PWM signal output from the inverter, in case of a perfect filter, would result in a DC voltage on the output Vₘₒₜₒᵣ. This means that the entire voltage drop occurs across the transformer primary winding L₁ which is the inductor component of the low-pass passive filtering circuit 14. The inductance is defined as the ratio of the induced voltage to the rate of change of current causing it, as expressed by the following formula:

$$L = \frac{V}{\frac{d i}{dt}} \to V = L \frac{d i}{d t}$$

Accordingly, in order to have a sufficient voltage drop across the transformer primary winding L₁, larger coils can be used to increase the inductance. However, as previously mentioned, the use of large coils to filter effectively the PWM components of the motor-driving signal in order to mitigate the signal ripple is not always a viable option when facing volume limitations.

Yet, the relationship between inductance and flux for a coil can be understood by considering that the magnetic flux φ is proportional to the current I in the coil and the number of turns N. Therefore, the inductance can be expressed as:

$$L = \frac{{N}^{2} Φ}{i}$$

Consequently, for boosting the inductance of a coil, the magnetic flux that is generated by a driving current can be boosted. In order to boost such magnetic flux, the current Iₚ at the output of the inverter 30 is first multiplied by the gain of the amplifier 18 to generate the compensating current Iₛ of a predetermined value. The compensating current is then injected in the transformer secondary winding L₂ to counteract the high-frequency PWM voltage component in the motor-driving PWM signal through the mutual inductance of the transformer 12 in order to at least attenuate the ripple in the signal.

The current Iₛ flowing in the secondary winding L₂ of the transformer 12 can therefore be expressed by the formula:

$${I}_{s} = β \cdot HF ( {I}_{p} )$$

where β is the gain of the amplifier 18 and HF (Ip) is the high-frequency components of the signal at the output of the power inverter 30.

The voltage drop Vₚ across the primary winding L₁ of the transformer is defined by the formula:

$${V}_{p} = {L}_{12} \cdot \frac{{dI}_{s}}{d t}$$

The mutual inductance L₁₂ of the transformer 12 therefore increases the voltage drop Vₚ. Given that the rate of change of the current Iₚ is directly proportional to the voltage Vₚ, a larger voltage across the transformer primary winding L₁ causes a steeper slope in the current waveform during the portions of the triangular signal where the voltage is constant. To minimize signal ripple as much as possible, the voltage across Vₚ must closely resemble a perfect square waveform as shown in FIG. 1.

The combination of the transformer primary winding L₁ and the capacitor C of the low-pass passive filter 14 filters out the high-frequency components of the square wave, leaving only the low-frequency or DC component at the output. The values of the capacitance C and of the resistance R of the RC circuit are chosen to have a large time constant to have a slower response and smoother filtering of high-frequency components of the signal such that the Vₘₒₜₒᵣ is as constant as possible.

The number of turns in the primary and secondary windings L₁, L₂ of the transformer 12, along with the amplifier's gain, can be selected based on the magnitude of the ripple that needs to be filtered to output a DC voltage to drive the electric motor. The transformer 12 can be dimensioned to bear the 30A foreseen peak current on the primary side with no saturation. The primary and secondary winding L₁, L₂ of the transformer can comprise for example 11 turns and 4 turns respectively.

The low-pass filtering circuit 14 can comprise a capacitance C and a resistance R in series and arranged in parallel with the primary winding L₁ of the transformer 12 which is the inductor component of the filtering circuit as shown in FIG. 2.

In an embodiment, the low-pass filtering circuit 14 can comprise an additional inductance L₃ mounted in series with the capacitance C and the resistance R as shown in FIG. 3 to have a second-order low-pass filter with a steeper attenuation slope

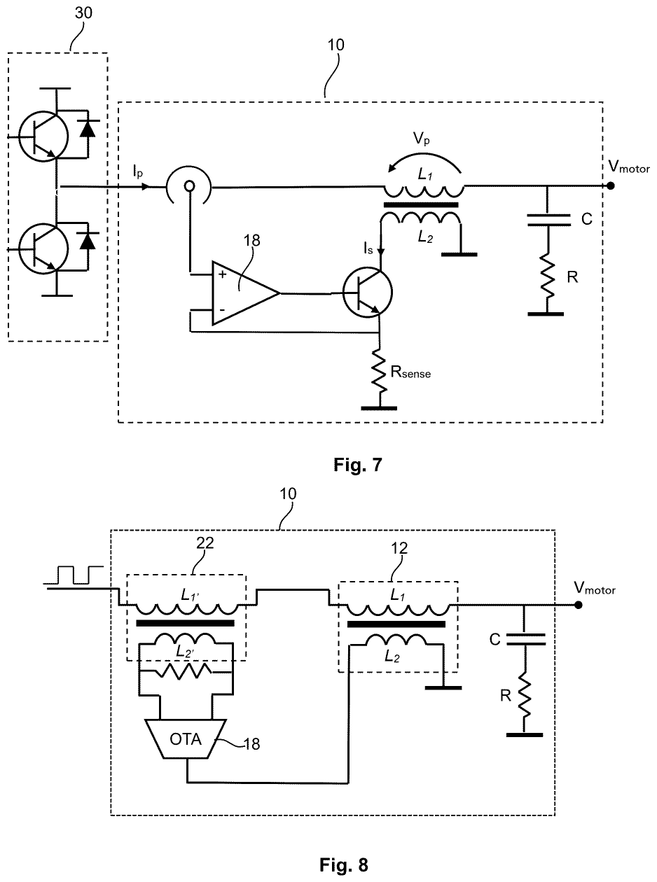

In an embodiment shown in FIG. 7, the low-pass active filter comprises an OTA 18 with a feedback loop. The resistance Rₛₑₙₛₑ is used to set the V-I current gain. This adds more precision with respect to an open loop OTA implementation as the feedback back loop allows to set precisely the amplifier gain.

In an embodiment shown in FIG. 8, the low-pass active filter 10 comprises a second transformer 22 having a primary winding L_{1′} and a secondary winding L_{2′}. The output of the primary winding L_{1′} of this second transformer 22 is connected to an input of the primary winding L₁ of the first transformer 12. An operational transconductance amplifier (OTA) 18 is used with its inputs connected to the terminals of the secondary winding L_{2′} of the second transformer 22 while the output of the amplifier 18 is injected into the secondary winding L₂ of the first transformer 12.

The OTA is preferred over a classical operational amplifier since a controlled current source is required for limiting the phase delay in the injected current with regard to the phase of the fundamental frequency of the current Iₚ in the primary winding L₁ of the first transformer 12. In fact, a small as possible delay as well as high enough current drive capability at the frequency of interest must be guaranteed. The injection transformer is the element where the flux is boosted. The winding turns ratio on primary and secondary windings can be selected according to the active part requirement.

In an embodiment, the current measurement is performed via the second transformer since the secondary winding, with many turns, produces a reduced current proportional to the primary current. Using a transformer for current measurement allows to add a natural high-pass filter, limit the loop delay and to naturally isolate the primary side to the secondary side.

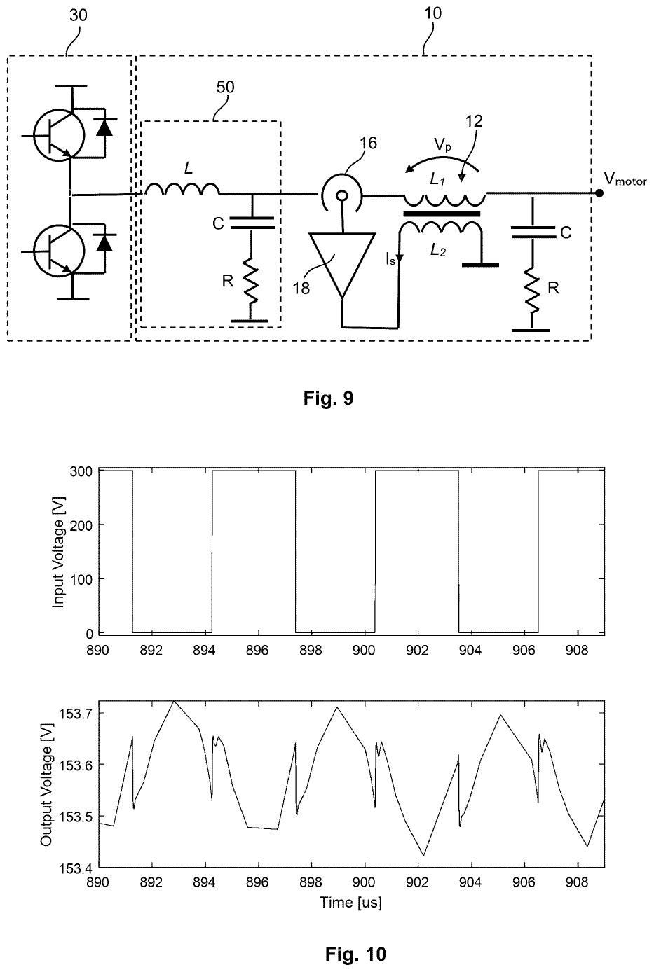

In an embodiment shown in FIG. 9, the low-pass active filter 10 further comprises a second low-pass passive filtering circuit 50 arranged to be connected to the output of the inverter 30 and to filter out the PWM signal before measurement of the current by the sensor current 16. This second low-pass passive filtering circuit 50 can be added to any of the above-described embodiments and can be for example of the type of a RLC filter.

FIG. 10 is a simulation of the low-pass active filter 10 showing a 300V PWM voltage at the input of the active filter and a residual 200 mV PWM voltage at the output of the filter for a switching PWM frequency of 160 kHz.

The low-pass active filter, as described herein, is primarily used in linear motors, especially synchronous motors in which the mover's coils are powered by a DC voltage. These linear motors are particularly suited for X-Y positioning stages in the semiconductor industry, such as in photolithography machines and wafer inspection systems, where positioning accuracy at the nanometre or sub-nanometre level is essential.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A low-pass active filter for a motor-driving PWM signal generated by a power inverter in an electric motor drive, comprising:
a first transformer having a primary winding and a secondary winding;
a first low-pass passive filtering circuit arranged to filter an output signal of the primary winding to power the electric motor;
a current sensor for measuring a current flowing on the low-pass active filter; and
an amplifier configured to generate and inject a compensating current into the secondary winding,
wherein the compensating current is the current measured by the current sensor multiplied by a gain of the amplifier,
wherein the primary winding of the first transformer is an inductor component of the first low-pass passive filtering circuit, and
wherein a gain of the amplifier is determined such that the compensating current is adapted to counteract a high-frequency PWM voltage component in the motor-driving PWM signal through a mutual inductance of the first transformer in order to at least attenuate ripple in the motor-driving PWM signal.

2. The low-pass active filter according to claim 1, further comprising a high-pass filter configured to extract high-frequency components of an output signal of the power inverter from the compensating current before the injection of said compensating current into the secondary winding.

3. The low-pass active filter according to claim 1, wherein the high pass-filter is arranged between the current sensor and the amplifier.

4. The low-pass active filter according to claim 1, wherein the current sensor is arranged on an input side or on an output side of the primary winding.

5. The low-pass active filter according to claim 1, wherein the current sensor is arranged to measure current flowing in an RC branch of the first low-pass passive filtering circuit.

6. The low-pass active filter according to claim 1, wherein the current sensor is a second transformer having a primary winding and a secondary winding, wherein an output of the primary winding is connected to an input of the primary winding of the first transformer, wherein inputs of the amplifier are connected to terminals of the secondary winding of the second transformer and wherein an output of the amplifier is injected into the secondary winding of the first transformer.

7. The low-pass active filter according to claim 1, wherein the amplifier is an operational transconductance amplifier, a linear amplifier or a class-D amplifier.

8. The low-pass active filter according to claim 1, further comprising a second low-pass passive filtering circuit arranged to be connected to an output of the inverter and to filter out the motor-driving PWM signal before measurement of the current by the current sensor.

9. The low-pass active filter according to claim 1, wherein the first low-pass passive filtering circuit comprises at least a capacitance and a resistance in series and arranged in parallel with the inductor component.

10. The low-pass active filter according to claim 9, wherein the first low-pass passive filtering circuit further comprises another inductor arranged in series with the resistance and capacitance.

11. The low-pass active filter according to claim 1, wherein the output of the secondary winding of the first transformer is connected to ground.

12. A motor drive comprising:
at least one power inverter; and at least one low-pass active filter according to claim 1 to filter out an output of the at least one power inverter.

13. An electric synchronous motor, comprising the motor drive according to claim 1 to drive the coils of a mover of the motor.

14. An X-Y positioning stage for a semiconductor processing equipment, in particular a photolithography machine or a wafer inspection system, comprising one or more electric synchronous motors according to claim 13.
